(19) United States
(12) Patent Application Publication
(10) Pub. No.: US 2025/0386709 A1
(43) Pub. Date: Dec. 18, 2025

(54) PROTECTING FILM AND ELECTRONIC DEVICE INCLUDING THE PROTECTING FILM

(71) Applicant: Samsung Display Co., LTD., Yongin-si (KR)

(72) Inventors: JUNGEUN LEE, Yongin-si (KR); JAECHUN PARK, Yongin-si (KR); Junsu Lee, Yongin-si (KR)

(21) Appl. No.: 19/062,443

(22) Filed: Feb. 25, 2025

(30) Foreign Application Priority Data
Jun. 18, 2024 (KR) 10-2024-0078846

(51) Int. Cl. H10K 59/80; H10K 102/00

(52) U.S. Cl. CPC H10K 59/871; H10K 2102/311

(57) ABSTRACT

A protecting film includes an attachment portion configured to be attached to an object and a protrusion portion protruding from one side of the attachment portion, including a first surface and a second surface opposite to the first surface. The protrusion portion may define a first cutout portion from which at least a portion is removed from the first surface. Accordingly, the protecting film may be prevented from being peeled off from the object by physical interference. In addition, as adhesive force of a film adhesive layer included in the protecting film may be lowered, the protecting film may be easily removed.

This application claims priority to Korean Patent Application No. 10-2024-0078846, filed on Jun. 18, 2024, and all the benefits accruing therefrom under 35 U.S.C. § 119, the content of which in its entirety is herein incorporated by reference.

### BACKGROUND

### 1. Field

The invention relates to a protecting film and an electronic device including the protecting film, and more particularly, to a protecting film including an adhesive layer and an electronic device including the protecting film.

### 2. Description of the Related Art

A display device is a device that displays an image for providing visual information to a user. Among display devices, an organic light emitting diode display device has recently attracted attention.

The display device may include a hole in which a camera is disposed. Foreign substances or pollutants may penetrate into the hole during manufacturing process of the display device.

### SUMMARY

Embodiments provide a protecting film in which a peeling off of the protecting film from an object is prevented.

Embodiments provide an electronic device including the protecting film.

A protecting film, according to an embodiment, includes an attachment portion configured to be attached to an object and a protrusion portion protruding from one side of the attachment portion, including a first surface and a second surface opposite to the first surface.

In an embodiment, the protrusion portion may define a first cutout portion from which at least a portion is removed from the first surface.

In an embodiment, the first cutout portion may be directed parallel to a boundary surface at which the attachment portion and the protrusion portion contact each other.

In an embodiment, the first cutout portion may be spaced apart from the second surface in a plan view.

In an embodiment, the attachment portion may include a base layer and a film adhesive layer bonding the base layer and the object.

In an embodiment, adhesive force of the film adhesive layer may be equal to or less than about 50 gf/inch.

In an embodiment, the protrusion portion may define a second cutout portion from which at least a portion is removed from the second surface.

In an embodiment, the first cutout portion and the second cutout portion may be directed parallel to each other.

In an embodiment, the protrusion portion may protrude from the one side of the attachment portion to be directed in a first direction.

In an embodiment, the first cutout portion and the second cutout portion may at least partially overlap each other in the first direction.

In an embodiment, the second cutout portion may be spaced apart from the first surface in a plan view.

In an embodiment, a boundary surface at which the attachment portion and the protrusion portion may contact each other extends in a first direction.

In an embodiment, the first cutout portion may include a first portion extending in the first direction and a second portion extending from one end of the first portion in a second direction crossing the first direction.

In an embodiment, the first cutout portion may be spaced apart from the attachment portion in a plan view.

A protecting film, according to an embodiment, includes a base layer including an attachment area attached to an object, a protrusion area protruding from the attachment area and a film adhesive layer disposed in the attachment area under the base layer.

In an embodiment, the base layer may define a cutout portion.

In an embodiment, the cutout portion may include a first portion extending in a first direction from a portion of the protrusion area and a second portion extending in a second direction crossing the first direction in a portion of the protrusion area and a portion of the attachment area.

In an embodiment, the first portion of the cutout portion may be directed parallel to a boundary surface at which the attachment area and the protrusion area contact each other.

In an embodiment, the second portion of the cutout portion may cross the boundary surface at which the attachment area and the protrusion area contact each other.

In an embodiment, the second portion of the cutout portion may be spaced apart from the film adhesive layer in a plan view.

In an embodiment, the first portion and the second portion of the cutout portion may be connected to each other.

An electronic device, according to an embodiment, includes a display panel, a protecting film disposed under the display panel and a memory where data information is stored.

In an embodiment, the protecting film may include an attachment portion configured to be attached to the display panel and a protrusion portion protruding from one side of the attachment portion and including a first surface and a second surface disposed opposite to the first surface.

In an embodiment, the protrusion portion may define a first cutout portion from which at least a portion is removed from the first surface.

In an embodiment, the first cutout portion may be directed parallel to a boundary surface at which the attachment portion and the protrusion portion contact each other.

In an embodiment, the display panel may define a hole, and the protecting film may at least partially overlap the hole in a plan view.

In an embodiment, a second cutout portion from which at least a portion may be removed from the second surface may be defined.

A protecting film, according to an embodiment, may include an attachment portion configured to be attached to an object and a protrusion portion protruding from one side of the attachment portion, including a first surface and a second surface disposed opposite to the first surface. The protrusion portion may define a first cutout portion from which at least a portion is removed from the first surface.

Accordingly, in an embodiment, the protecting film may be prevented from being peeled off from the object by physical interference. In addition, in an embodiment, as adhesive force of a film adhesive layer included in the protecting film may be lowered, the protecting film may be easily removed.

### BRIEF DESCRIPTION OF THE DRAWINGS

Illustrative, non-limiting embodiments will be more clearly understood from the following detailed description in conjunction with the accompanying drawings.

FIG. 1A is a perspective view illustrating a display device, according to an embodiment.

FIG. 1B is a perspective view illustrating a state in which the display device of FIG. 1A is folded, according to an embodiment.

FIG. 2 is a cross-sectional view illustrating a stacked structure of the display device of FIG. 1, according to an embodiment.

FIG. 3 is a cross-sectional view illustrating a stacked structure of a display module, according to an embodiment.

FIG. 4 is a perspective view illustrating a stacked structure of the display module of FIG. 3, according to an embodiment.

FIG. 5 is a bottom view illustrating a process of removing a portion of a release film included in the display module of FIG. 3 and attaching a protecting film to a display panel, according to an embodiment.

FIG. 6 is a bottom view illustrating a process of removing a portion of a release film included in the display module of FIG. 3 and attaching a protecting film to a display panel, according to an embodiment.

FIG. 7 is a bottom view illustrating a process of removing a portion of a release film included in the display module of FIG. 3 and attaching a protecting film to a display panel, according to an embodiment.

FIG. 8 is a bottom view illustrating a protecting film, according to an embodiment.

FIG. 9 is a perspective view illustrating a state in which shape of the protecting film of FIG. 8 is deformed due to physical interference, according to an embodiment.

FIG. 10 is a cross-sectional view of the protecting film of FIG. 8 taken along line I-I, according to an embodiment.

FIG. 11 is a cross-sectional view illustrating pixels included in the display panel of FIG. 4, according to an embodiment.

FIG. 12 is a bottom view illustrating a protecting film, according to an embodiment.

FIG. 13 is a bottom view illustrating a protecting film, according to an embodiment.

FIG. 14 is a bottom view illustrating a protecting film, according to an embodiment.

FIG. 15 is a bottom view illustrating a protecting film, according to an embodiment.

FIG. 16 is a bottom view illustrating a protecting film, according to an embodiment.

FIG. 17 is a block diagram illustrating an electronic device, according to embodiments.

FIG. 18 illustrates graphical images of various electronic devices, according to various embodiments.

### DETAILED DESCRIPTION

Hereinafter, display devices, in accordance with an embodiment, will be described in more detail with reference to the accompanying drawings. The same reference numerals are used for the same components in the drawings, and redundant descriptions of the same components will be omitted.

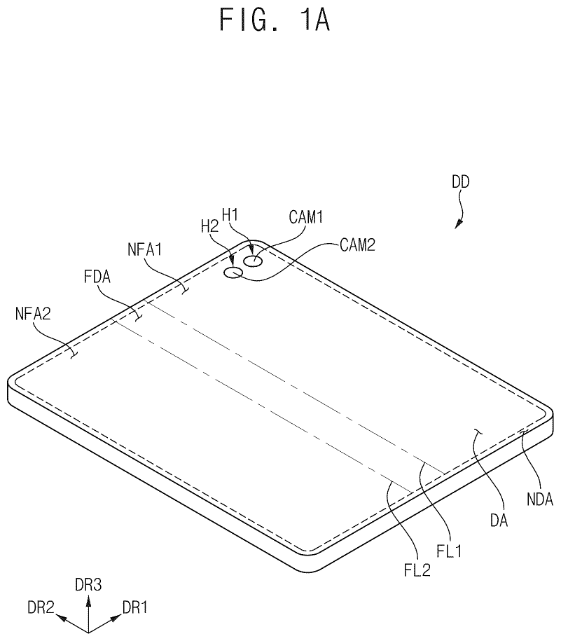

FIG. 1A is a perspective view illustrating a display device, according to an embodiment. FIG. 1B is a perspective view illustrating a state in which the display device of FIG. 1A is folded, according to an embodiment.

In an embodiment and referring to FIGS. 1A and 1B, a display device DD may be a device activated by an electrical signal. For example, the display device DD may be a small display device used in small electronic device such as smartphone, mobile phone, smart watches, game console, cameras and/or the like. However, the invention is not limited thereto, and the display device DD may be a medium to large-sized display device used in medium to large-sized electronic device such as laptop, tablet PC, television, computer monitor, vehicle monitor, external billboard, and/or the like.

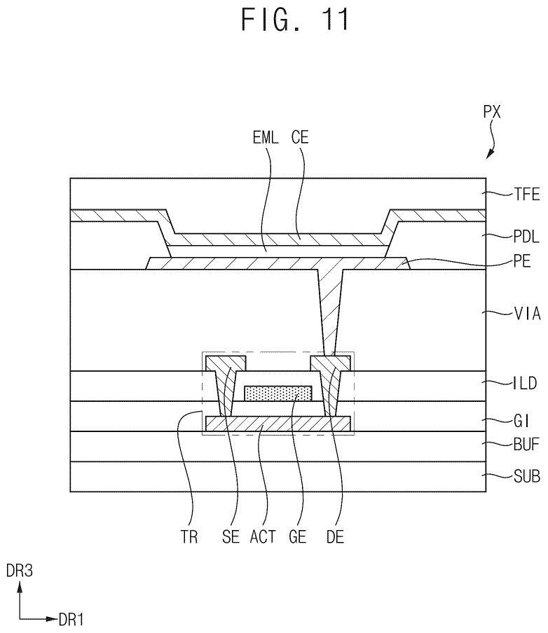

In an embodiment, the display device DD may include a display area DA and a non-display area NDA, where the display area DA may be an area that generates light or adjusts a transmittance of light provided from an external light source to display an image. For example, a pixel (e.g., a pixel PX of FIG. 11) may be disposed in the display area DA.

In an embodiment, the non-display area NDA may be disposed around the display area DA. For example, the non-display area NDA may surround at least a portion of the display area DA. In an embodiment, the non-display area NDA may be an area in which an image is not displayed. However, the invention is not limited thereto, and an image may be displayed in at least a portion of the non-display area NDA. For example, a light emitting element that emits light may be disposed in at least a portion of the non-display area NDA.

In an embodiment, the display device DD may maintain a folded state and an unfolded state. For example, the display device DD may be folded in an in-folding method in which the display area DA is disposed inside as illustrated in FIG. 1B. When the display device DD is folded in the in-folding method, front surfaces of the display device DD may face each other. However, the invention is not limited thereto, and the display device DD may be folded in an out-folding method in which the display area DA is disposed outside. When the display device DD is folded in the out-folding method, rear surfaces of the display device DD may face each other.

In an embodiment, the display device DD may include a folding area FDA, a first non-folding area NFA1, and a second non-folding area NFA2, where the folding area FDA may be an area in which the display device DD is bent or folded. The first non-folding area NFA1 and the second non-folding area NFA2 may be areas in which the display device DD is not bent or folded. A first folding line FL1 may be a boundary disposed between the folding area FDA and the first non-folding area NFA1. A second folding line FL2 may be a boundary disposed between the folding area FDA and the second non-folding area NFA2. For example, the first folding line FL1 and the second folding line FL2 may be directed parallel to each other.

In an embodiment, the first non-folding area NFA1 may contact the folding area FDA. The first non-folding area NFA1 may contact one side of the folding area FDA. In an embodiment, as illustrated in FIGS. 1A and 1B, the first non-folding area NFA1 may contact right side of the folding area FDA.

In an embodiment, the second non-folding area NFA2 may contact the folding area FDA. The second non-folding area NFA2 may contact other side of the folding area FDA. In an embodiment, as illustrated in FIGS. 1A and 1B, the second non-folding area NFA2 may contact left side of the folding area FDA. The folding area FDA may be disposed between the first non-folding area NFA1 and the second non-folding area NFA2.

In an embodiment, as illustrated in FIGS. 1A and 1B, each of the first folding line FL1 and the second folding line FL2 may extend in a second direction DR2. In this case, the display device DD may be folded in a first direction DR1. Accordingly, length of the display device DD in the first direction DR1 may be reduced by approximately half. Accordingly, it may be convenient for a user to carry the display device DD.

However, the invention is not limited thereto, and the display device DD may not include the folding area FDA. In this case, the display device DD may not be bent or folded.

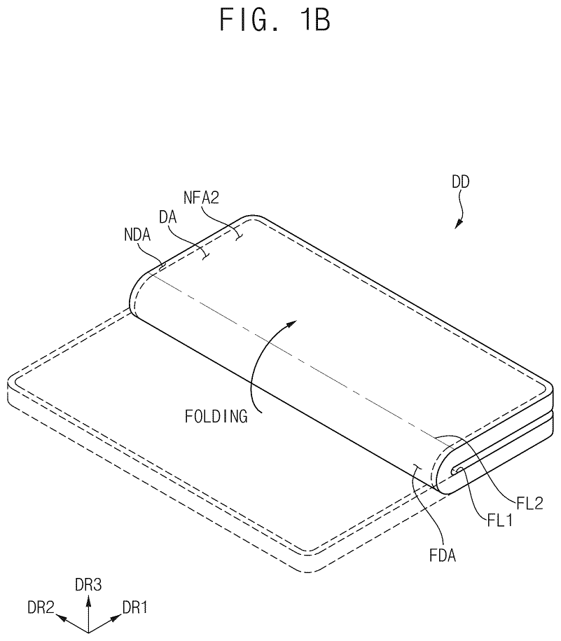

In an embodiment, the display device DD may include (or define) a first hole H1 and a second hole H2, where each of the first hole H1 and the second hole H2 may be a portion penetrating at least a portion of the display device DD in a thickness direction of the display device DD. That is, each of the first hole H1 and the second hole H2 may be a portion penetrating at least a portion of the display device DD in a third direction DR3. For example, each of the first hole H1 and the second hole H2 may be a portion penetrating at least a portion of a display panel (for example, a display panel 10 of FIG. 2) in the third direction DR3. However, the invention is not limited thereto, and each of the first hole H1 and the second hole H2 may be a portion penetrating a configuration different from the display panel in the third direction DR3.

In an embodiment, each of the first hole H1 and the second hole H2 may be disposed in the display area DA. However, the invention is not limited thereto, and in an embodiment, some of the first hole H1 and the second hole H2 may be disposed in the display area DA, and other may be disposed in the non-display area NDA. For example, the first hole H1 may be disposed in the non-display area NDA, and the second hole H2 may be disposed in the display area DA. In an embodiment, each of the first hole H1 and the second hole H2 may be disposed in the non-display area NDA.

In an embodiment, a camera, a speaker, a sensor, and/or the like may be disposed in each of the first hole H1 and the second hole H2. For example, a first camera CAM1 may be disposed in the first hole H1, and a second camera CAM2 may be disposed in the second hole H2, but this disclosure is not limited thereto. The first camera CAM1 may be exposed by the first hole H1. The second camera CAM2 may be exposed by the second hole H2.

In an embodiment, the first direction DR1 and the second direction DR2 crossing the first direction DR1 may be defined. For example, the second direction DR2 may be directed to be substantially perpendicular to the first direction DR1. However, the invention is not limited thereto, and the second direction DR2 may form an acute angle or an obtuse angle with the first direction DR1. In addition, a third direction DR3 crossing a plane formed by the first direction DR1 and the second direction DR2 may be defined. For example, the third direction DR3 may be directed to be substantially perpendicular to the plane formed by the first direction DR1 and the second directions DR2. However, the invention is not limited thereto, and the third direction DR3 may form an acute angle or an obtuse angle with the plane formed by the first direction DR1 and the second direction DR2.

FIG. 2 is a cross-sectional view illustrating a stacked structure of the display device of FIG. 1, according to an embodiment.

In an embodiment and referring to FIG. 2, the display device DD may include a display panel 10, a first adhesive layer AD1, a polarizing plate 20, a second adhesive layer AD2, and a cover window 30.

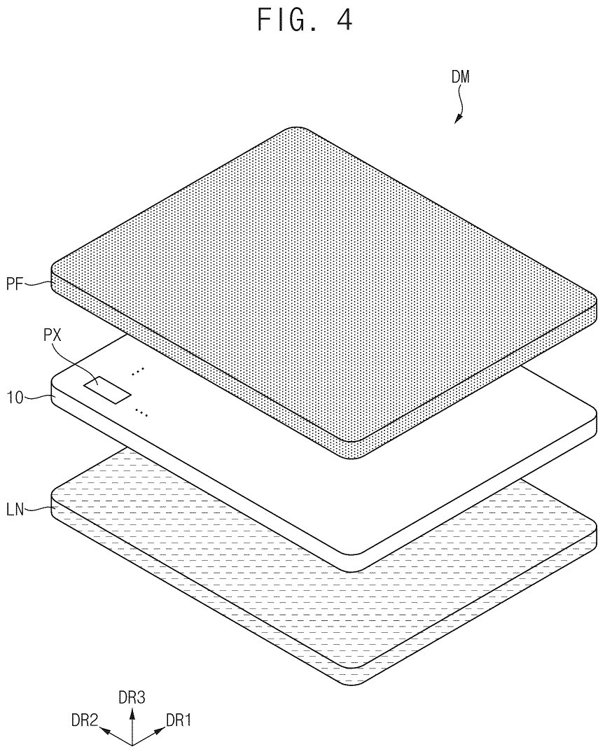

In an embodiment, the display panel 10 may emit light. For example, the display panel 10 may include a plurality of pixels, and each of the pixels may emit light. For example, the display panel 10 may include a pixel (e.g., a pixel PX of FIG. 4), and the pixel may emit light. A cross-sectional structure of the pixel will be described later with reference to FIG. 11.

In an embodiment, the polarizing plate 20 may be disposed on the display panel 10, where the polarizing plate 20 may absorb a portion of light introduced from an outside of the display device DD to reduce reflected light due to external light.

In an embodiment, the display panel 10 and the polarizing plate 20 may be attached to each other by the first adhesive layer AD1. That is, the first adhesive layer AD1 may be disposed between the display panel 10 and the polarizing plate 20. For example, the first adhesive layer AD1 may include an optical clear resin (“OCA”), an optical clear resin (“OCR”), or a pressure sensitive adhesive (“PSA”).

In an embodiment, the cover window 30 may be disposed on the polarizing plate 20, where the cover window 30 may transmit light emitted from the display panel 10. The cover window 30 may include an insulating material such as transparent plastic or glass.

In an embodiment, the polarizing plate 20 and the cover window 30 may be attached to each other by the second adhesive layer AD2. That is, the second adhesive layer AD2 may be disposed between the polarizing plate 20 and the cover window 30. For example, the second adhesive layer AD2 may include an OCA, an OCR, or a PSA.

In an embodiment, FIG. 2 may illustrate an exemplary stacked structure of the display device DD, and the display device DD may further include other components in addition to the above-described components. For example, in another embodiment, the display device DD may further include a protecting film, a heat dissipation member, a shielding member, and/or the like.

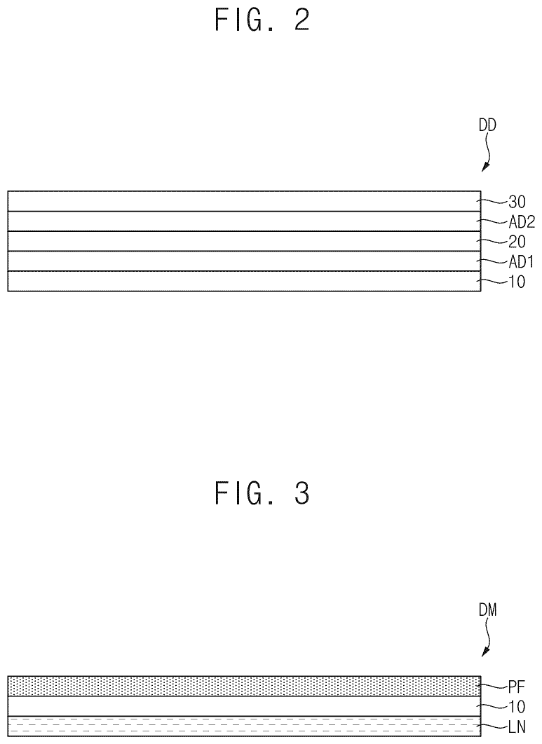

FIG. 3 is a cross-sectional view illustrating a stacked structure of a display module, according to an embodiment. FIG. 4 is a perspective view illustrating a stacked structure of the display module of FIG. 3, according to an embodiment.

In an embodiment and referring to FIGS. 3 and 4, a display module DM may include a display panel 10, a release film LN, and a panel protecting film PF. That is, the display module DM may include the release film LN and the panel protecting film PF, unlike the display device DD illustrated in FIG. 2.

In an embodiment, the display panel 10 may include a plurality of pixels. For example, the display panel 10 may include a pixel PX, where each of the plurality of pixels may emit light. For example, the pixel PX may emit light.

In an embodiment, the panel protecting film PF may be disposed on the display panel 10 and may protect the display panel 10 during a manufacturing process of the display device (e.g., the display device DD of FIG. 1). For example, panel protecting film PF may include polyether sulfone (“PES”), polyacrylate, polyetherimide (“PEI”), polyethylene naphthalate (“PEN”), polyethylene terephthalate (“PET”), polyphenylene sulfide (“PPS”), polyarylate, polyimide (“PI”), polycarbonate (“PC”), poly(arylene ether sulfone), and/or the like. These materials may be used alone or in combination with each other. However, the invention is not limited thereto, and a material used as a panel protecting film PF may be variously changed according to embodiments.

In an embodiment, the release film LN may be disposed under the display panel 10 and may include PEN, PET, and/or the like. These materials may be used alone or in combination with each other. However, the invention is not limited thereto.

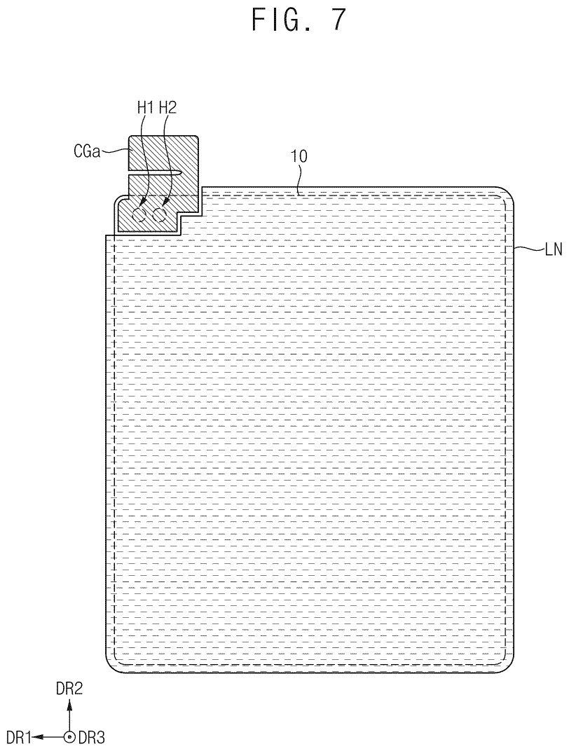

In an embodiment, the panel protecting film PF, the release film LN, and a protecting film (e.g., a protecting film CGa of FIG. 7) to be described below may be removed from the display panel 10 during a manufacturing process of the display device (e.g., the display device DD of FIG. 1). Thereafter, the display panel 10 may be assembled with various sets (e.g., bracket, electronic component, and/or the like) to be provided to various types of display device (e.g., the display device DD of FIG. 1).

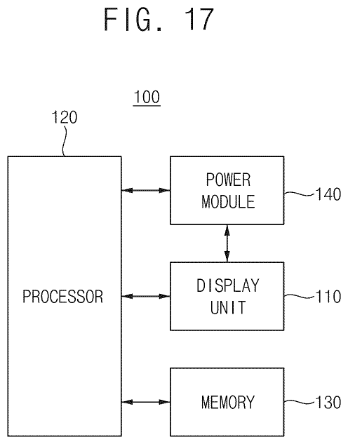

In an embodiment, some of the panel protecting film PF, the release film LN, and the protecting film may be removed during manufacturing process of an electronic device (for example, an electronic device 100 of FIG. 17). For example, the release film LN and the protecting film may be removed during the manufacturing process of the electronic device. In this case, the display panel 10 may be applied to the electronic device while the release film LN and the protecting film are attached to the display panel 10. Thereafter, the release film LN and the protecting film may be removed from the display panel 10.

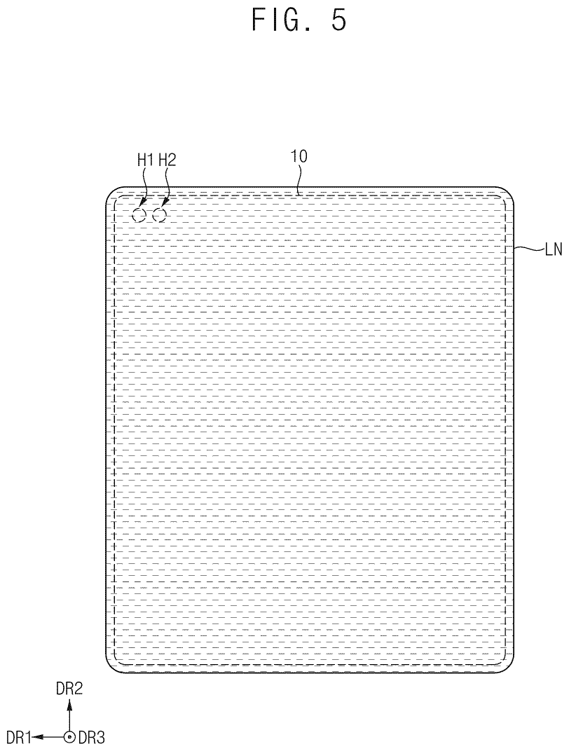

FIGS. 5, 6, and 7 are bottom views illustrating an embodiment of a process of removing a portion of a release film included in the display module of FIG. 3 and attaching a protecting film to a display panel.

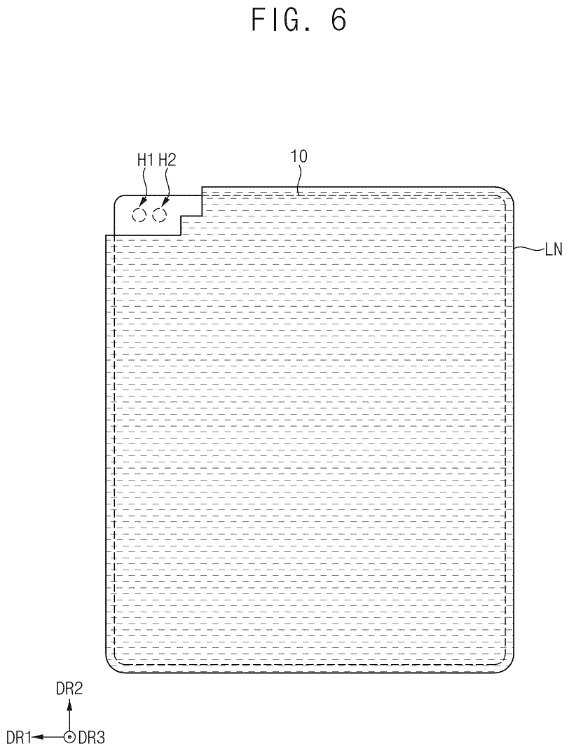

In an embodiment and referring to FIGS. 5 and 6, the release film LN may be attached to a lower portion of the display panel 10. As described above, the display device (e.g., the display device DD of FIG. 1) may include (or define) the first hole H1 and the second hole H2. In addition, the first camera (e.g., the first camera CAM1 of FIG. 1) may be disposed in the first hole H1, and the second camera (e.g., the second camera CAM2 of FIG. 1) may be disposed in the second hole H2.

In an embodiment, in order to check whether light is well transmitted to the first hole H1 and the second hole H2 (or the first camera and the second camera), a light transmittance test may be performed on the first hole H1 and the second hole H2. In this case, a portion of the release film LN may be partially removed. For example, a portion of the release film LN overlapping the first hole H1 and the second hole H2 in a plan view may be removed. For example, an edge portion of the release film LN may be removed. Accordingly, the first hole H1 and the second hole H2 may be exposed, and the light transmittance test may be performed on the first hole H1 and the second hole H2.

In an embodiment and referring to FIG. 7, after the light transmittance test on the first hole H1 and the second hole H2 is performed, a protecting film CGa may be attached to a lower portion of the display panel 10. For example, the protecting film CGa may be attached to a portion where the first hole H1 and the second hole H2 are disposed. That is, the protecting film CGa may at least partially overlap the first hole H1 and the second hole H2 in a plan view. That is, the protecting film CGa may be attached to a portion where the release film LN is partially removed from the lower portion of the display panel 10. Accordingly, the protecting film CGa may prevent foreign substances or pollutants from penetrating into the first hole H1 and the second hole H2. That is, the protecting film CGa may prevent foreign substances or pollutants from penetrating into the first hole H1 and the second H2 during manufacturing process of the display device (e.g., the display device DD of FIG. 1)) (or, manufacturing process of the electronic device (e.g., the electronic device 100 of FIG. 17)). As the protecting film CGa is a component disposed under the display panel 10 during the manufacturing process of the display device, the protecting film CGa may be understood as a component included in the display module (for example, the display module DM of FIG. 4).

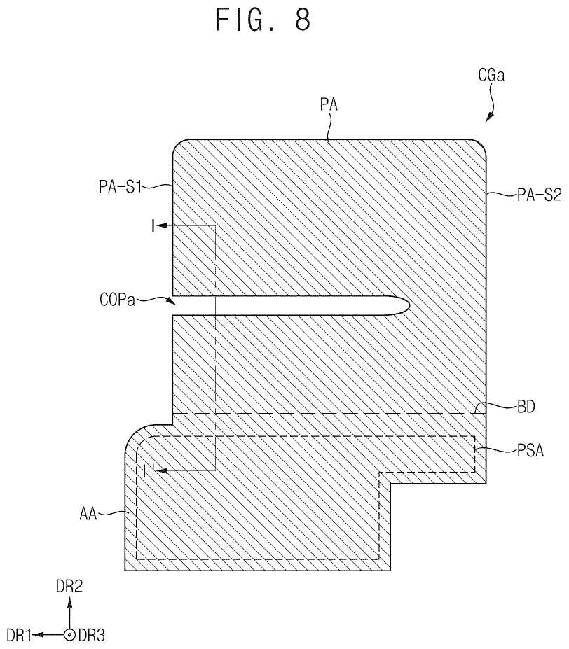

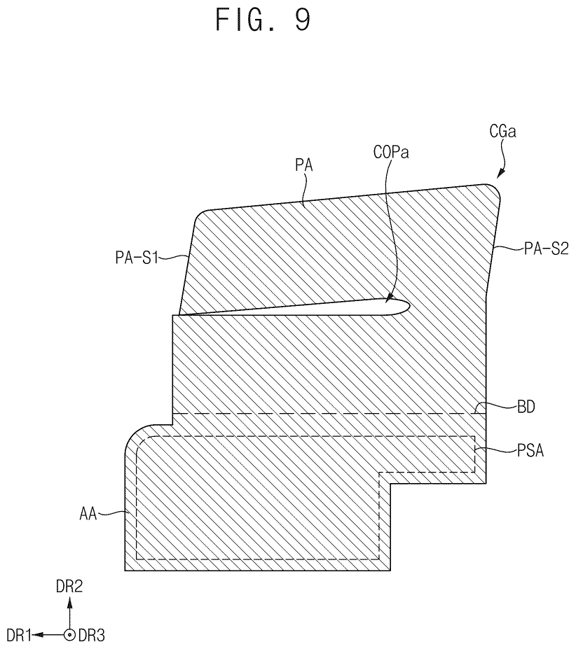

FIG. 8 is a bottom view illustrating a protecting film, according to an embodiment. FIG. 9 is a perspective view illustrating a state in which shape of the protecting film of FIG. 8 is deformed due to physical interference, according to an embodiment.

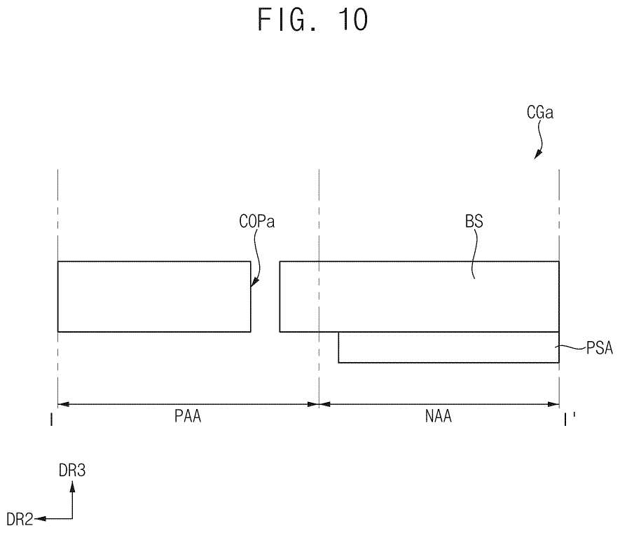

In an embodiment and referring to FIGS. 7 and 8, the protecting film CGa may include an attachment portion AA and a protrusion portion PA. The attachment portion AA may be a portion disposed in an attachment area (e.g., an attachment area NAA of FIG. 10). The protrusion portion PA may be a portion disposed in a protrusion area (e.g., a protrusion area PAA of FIG. 10).

In an embodiment, the attachment portion AA may be a portion attached to an object, where the object may mean the display panel 10. However, the invention is not limited thereto, and the object may mean a component that is different from the display panel 10 included in the display device (e.g., the display device DD of FIG. 1). In an embodiment, the attachment portion AA may include a film adhesive layer PSA. Through the film adhesive layer PSA, the attachment portion AA may be attached to the object. For example, a base layer (e.g., a base layer BS of FIG. 10) disposed in the attachment area may be attached to the object through the film adhesive layer PSA.

In an embodiment, the protrusion portion PA may protrude (or extend) from one side of the attachment portion AA. For example, the protrusion portion PA may protrude from the one side of the attachment portion AA to a portion where the object is not disposed. For example, the protrusion portion PA may protrude from the one side of the attachment portion AA in the second direction DR2. The protrusion portion PA may be a grabbing portion held by a user when the protecting film CGa is removed from the display panel 10. That is, as the protecting film CGa includes the protrusion portion PA, it may be easy to remove the protecting film CGa from the display panel 10. As the protecting film CGa includes the attachment portion AA and the protrusion portion PA, a boundary surface BD at which the attachment portion AA and the protrusion portion PA contact each other may be defined. For example, the boundary surface BD may extend in the first direction DR1, but the invention is not limited thereto.

In an embodiment, the protrusion portion PA may include a first surface PA-S1 and a second surface PA-S2. For example, each of the first surface PA-S1 and the second surface PA-S2 may be a surface that is directed parallel to a plane formed by the second direction DR2 and the third direction DR3. The second surface PA-S2 may be a surface opposite to the first surface PA-S1. For example, the first surface PA-S1 may be a surface facing toward the first direction DR1, and the second surface PA-S2 may be a surface facing toward a direction opposite to the first direction DR1.

In an embodiment, the protrusion portion PA may include (or define) a first cutout portion COPa, where the first cutout portion COPa may be a portion obtained by removing at least a portion of the protrusion portion PA from the first surface PA-S1. In an embodiment, the first cutout portion COPa may be directed to be substantially parallel to the boundary surface BD at which the protrusion portion PA and the attachment portion AA contact each other. That is, the first cutout portion COPa may extend in the first direction DR1. However, the invention is not limited thereto, and in an embodiment, the first cutout portion COPa may form an acute angle or an obtuse angle with the boundary surface BD at which the protrusion portion PA and the attachment portion AA contact each other. In this case, an angle formed by the first cutout portion COPa with the boundary surface BD may be variously changed according to embodiments. In an embodiment, the first cutout portion COPa may be spaced apart from the second surface PA-S2 in a plan view. That is, the width of the first cutout portion COPa in the first direction DR1 may be smaller than the width of the protrusion portion PA in the first direction DR1. In an embodiment, the first cutout portion COPa may be spaced apart from the attachment portion AA in a plan view. That is, the first cutout portion COPa may be a component that is included in the protrusion portion PA and that is not included in the attachment portion AA. In an embodiment, the first cutout portion COPa may have a linear shape extending in the first direction DR1 in a plan view. However, the invention is not limited thereto, and shape of the first cutout portion COPa in a plan view may be variously changed according to embodiments.

In an embodiment, while the protecting film CGa is attached to the object, the protecting film CGa may receive physical interference. For example, the object and the protecting film CGa may move or undergo various inspections while being attached to each other. In this process, the protecting film CGa may receive physical interference. For example, the protrusion portion PA of the protecting film CGa may receive physical interference, and the physical interference may propagate to the attachment portion AA and the film adhesive layer PSA. Accordingly, the film adhesive layer PSA and the attachment portion AA may be peeled off from the object. That is, a portion of the protecting film CGa may be peeled off from the object. Accordingly, foreign substances, pollutants, and/or the like may penetrate into the first hole H1 and the second hole H2.

In an embodiment and referring further to FIG. 9, as described above, the protrusion portion PA of the protecting film CGa may define the first cutout portion COPa. Accordingly, even when the protrusion portion PA is subjected to the physical interference, the physical interference may not be propagated to the attachment portion AA and the film adhesive layer PSA. That is, the physical interference received by the protrusion portion PA may be blocked by the first cutout portion COPa and thus may not be propagated to the attachment portion AA and the film adhesive layer PSA. Accordingly, only a portion of the protrusion portion PA may move or be deformed in the third direction DR3 or in a direction opposite to the third direction DR3, and the attachment portion AA and the film adhesive layer PSA may not be affected by the physical interference. Therefore, a portion of the protecting film CGa may be prevented from being peeled off from the object.

In an embodiment, when it is determined that light transmittance of the first hole H1 and the second hole H2 is good through the light transmittance test for the first hole H1 and the second hole H2, the protecting film CGa may be removed from the object. In this case, as adhesion force of the film adhesive layer PSA is higher, it may not be easy to remove the protecting film CGa from the object. As described above, as the protrusion portion PA includes the first cutout portion COPa, the protecting film CGa may be prevented from being peeled from the object by the physical interference. Accordingly, even when the adhesive force of the film adhesive layer PSA is low, the protecting film CGa may not be peeled off from the object. Accordingly, the adhesive force of the film adhesive layer PSA may be lowered, and the protecting film CGa may be easily removed from the object. For example, the adhesive force of the film adhesive layer PSA may be set to equal to or less than about 50 gf/inch. For example, the adhesive force of the film adhesive layer PSA may be set to equal to or greater than about 0 gf/inch and equal to or less than about 50 gf/inch.

FIG. 10 is a cross-sectional view of the protecting film of FIG. 8 taken along line I-I, according to an embodiment.

In an embodiment and referring to FIGS. 8 and 10, the protecting film CGa may include a protrusion area PAA and an attachment area NAA, where the attachment area NAA of the protecting film CGa may be an area attached to the object. The protrusion area PAA of the protecting film CGa may be an area protruding (or extending) from the attachment area NAA.

In an embodiment, the protecting film CGa may include the base layer BS and the film adhesive layer PSA. As the protecting film CGa includes the protrusion area PAA and the attachment area NAA, the base layer BS may also include the protrusion area PAA and the attachment area NAA. That is, the base layer BS may be disposed in the protrusion area PAA and the attachment area NAA. The film adhesive layer PSA may be disposed under the base layer BS. That is, the film adhesive layer PSA may attach the base layer BS and the object to each other. The film adhesive layer PSA may be disposed in the attachment area NAA and may not be disposed in the protrusion area PAA.

In an embodiment and as described above, the protrusion portion PA may define the first cutout portion COPa. That is, the base layer BS may define the first cutout portion COPa in the protrusion area PAA, where the first cutout portion COPa may penetrate (or defined through) the base layer BS in a thickness direction of the base layer BS. That is, the first cutout portion COPa may penetrate the base layer BS in the third direction DR3. For example, the first cutout portion COPa may be a portion obtained by removing the base layer BS from an upper surface of the base layer BS to a lower surface of the base layer BS.

For example, in an embodiment, the base layer BS may include PES, polyacrylate, PEI, PEN, PET, PPS, polyarylate, PI, PC, poly(arylene ether sulfone), and/or the like. These materials may be used alone or in combination with each other. For example, the film adhesive layer PSA may include an OCA, an OCR, or a PSA.

In an embodiment, a portion of the base layer BS disposed in the attachment area NAA and the film adhesive layer PSA may form the attachment portion AA. In addition, a portion of the base layer BS disposed in the protrusion area PAA may form the protrusion portion PA.

FIG. 11 is a cross-sectional view illustrating pixels included in the display panel of FIG. 4, according to an embodiment.

In an embodiment and referring to FIG. 11, the pixel PX may include a substrate SUB, a buffer layer BUF, a gate insulating layer GI, an interlayer insulating layer ILD, a via insulating layer VIA, an active layer ACT, a source electrode SE, a gate electrode GE, a drain electrode DE, a pixel electrode PE, a pixel defining layer PDL, a light emitting layer EML, a common electrode CE, and an encapsulating layer TFE.

In an embodiment, the transistor TR may include the active layer ACT, the source electrode SE, the gate electrode GE, and the drain electrode DE.

In an embodiment, the substrate SUB may include a transparent material or an opaque material and may be formed of a transparent resin substrate. Example of the transparent resin substrate may include a polyimide substrate. In this case, the polyimide substrate may include a first organic layer, a first barrier layer, a second organic layer, and the like.

Optionally, in another embodiment, the substrate SUB may include a quartz substrate (e.g. a synthetic quartz substrate, a fluorine-doped quartz substrate), a calcium fluoride substrate, a sodalime glass substrate, a non-alkali glass substrate, or the like. These materials may be used alone or in combination with each other.

In an embodiment, the buffer layer BUF may be disposed on the substrate SUB, where the buffer layer BUF may prevent metal atoms or impurities from diffusing from the substrate SUB to the transistor TR. In addition, the buffer layer BUF can improve flatness of a surface of the substrate SUB when the surface of the substrate SUB is not uniform.

For example, in an embodiment, the buffer layer BUF may include an inorganic material such as silicon oxide, silicon nitride, silicon oxynitride, or the like. These materials may be used alone or in combination with each other.

In an embodiment, the active layer ACT may be disposed on the buffer layer BUF and may include an inorganic semiconductor (e.g., amorphous silicon, polysilicon, a metal oxide semiconductor), an organic semiconductor, or the like. These materials may be used alone or in combination with each other. The active layer ACT may include a source area, a drain area, and a channel area disposed between the source area and the drain area.

In an embodiment, the metal oxide semiconductor may include a binary compound (“ABₓ”), a ternary compound (“ABₓC_{y}”), a quaternary compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other.

For example, in an embodiment, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

In an embodiment, the gate insulating layer GI may be disposed on the buffer layer BUF, where the gate insulating layer GI may sufficiently cover the active layer ACT. For example, the gate insulating layer GI may cover the active layer ACT and may be disposed along a profile of the active layer ACT.

For example, in an embodiment, the gate insulating layer GI may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

In an embodiment, the gate electrode GE may be disposed on the gate insulating layer GI and may overlap the channel area of the active layer ACT in the plan view.

In an embodiment, the gate electrode GE may include a metal, an alloy, a metal nitride, a conductive metal oxide, a transparent conductive material, or the like. Examples of the metal may include silver (“Ag”), molybdenum (“Mo”), aluminum (“AI”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

Examples of the conductive metal oxide may include Indium tin oxide, indium zinc oxide, or the like. These materials may be used alone or in combination with each other. In addition, examples of the metal nitride may include aluminum nitride (“AlN,”), tungsten nitride (“WNₓ”), chromium nitride (“CrNₓ”), or the like. These materials may be used alone or in combination with each other.

In an embodiment, the interlayer insulating layer ILD may be disposed on the gate insulating layer GI and may sufficiently cover the gate electrode GE. For example, the interlayer insulating layer ILD may cover the gate electrode GE, and may be disposed along a profile of the gate electrode GE.

For example, in an embodiment, the interlayer insulating layer ILD may include inorganic materials such as silicon oxide, silicon nitride, silicon carbide, silicon oxynitride, silicon oxycarbide, or the like. These materials may be used alone or in combination with each other.

In an embodiment, the source electrode SE may be disposed on the interlayer insulating layer ILD and may be connected to the source area of the active layer ACT through a contact hole penetrating the gate insulating layer GI and the interlayer insulating layer ILD.

In an embodiment, the drain electrode DE may be disposed on the interlayer insulating layer ILD and may be connected to the drain area of the active layer ACT through a contact hole penetrating the gate insulating layer GI and the interlayer insulating layer ILD.

For example, in an embodiment, the source electrode SE may include a metal, an alloy, a metal nitride, a conductive metal oxide, a transparent conductive material, or the like. These materials may be used alone or in combination with each other. The drain electrode DE and the source electrode SE may be formed through the same process and may include the same material.

In an embodiment, the via insulating layer VIA may be disposed on the interlayer insulating layer ILD, where the via insulating layer VIA may sufficiently cover the source electrode SE and the drain electrode DE. The via insulating layer VIA may include an organic material. For example, the via insulating layer VIA may include organic materials such as phenolic resin, acrylic resin, polyimide resin, polyamide resin, siloxane resin, epoxy resin, or the like. These materials may be used alone or in combination with each other.

In an embodiment, the pixel electrode PE may be disposed on the via insulating layer VIA and may be connected to the drain electrode DE through a contact hole penetrating the via insulating layer VIA.

In an embodiment, the pixel electrode PE may include a metal, an alloy, a metal nitride, a conductive metal oxide, a transparent conductive material, or the like. These materials be used alone or in combination with each other. In an embodiment, the pixel electrode PE may have a stacked structure including ITO/Ag/ITO. For example, the pixel electrode PE may operate as an anode.

In an embodiment, the pixel defining layer PDL may be disposed on the via insulating layer VIA and may cover side portions of the pixel electrode PE. In addition, an opening exposing a portion of the upper surface of the pixel electrode PE may be defined in the pixel defining layer PDL.

For example, in an embodiment, the pixel defining layer PDL may include an inorganic material or an organic material. In an embodiment, the pixel defining layer PDL may include an organic material such as an epoxy resin, a siloxane resin, or the like. These materials may be used alone or in combination with each other. In an embodiment, the pixel defining layer PDL may further include a light blocking material containing a black pigment, a black dye, or the like.

In an embodiment, the light emitting layer EML may be disposed on the pixel electrode PE and may include an organic material that emits light of a predetermined color. For example, the light emitting layer EML may include an organic material that emits red light. However, the invention is not limited thereto, and the light emitting layer EML may emit light of a different color from red light.

In an embodiment, the common electrode CE may be disposed on the light emitting layer EML and the pixel defining layer PDL. The common electrode CE may include a metal, an alloy, a metal nitride, a conductive metal oxide, a transparent conductive material, or the like. These materials may be used alone or in combination with each other. The common electrode CE may operate as a cathode.

In an embodiment, the encapsulation layer TFE may be disposed on the common electrode CE. The encapsulation layer TFE may prevent impurities and moisture from penetrating into the pixel electrode PE, the light emitting layer EML, and the common electrode CE from the outside. The encapsulation layer TFE may include at least one inorganic layer and at least one organic layer.

For example, in an embodiment, the inorganic layer may include silicon oxide, silicon nitride, silicon oxynitride, or the like. These materials may be used alone or in combination with each other. The organic layer may include a polymer cured product such as polyacrylate.

Although an embodiment of the pixel PX has been described with reference to FIG. 11, the pixel PX is not limited to the structure illustrated in FIG. 11. That is, the pixel PX may include all structures that receive an electrical signal and emit light having a luminance corresponding to the intensity of the electrical signal.

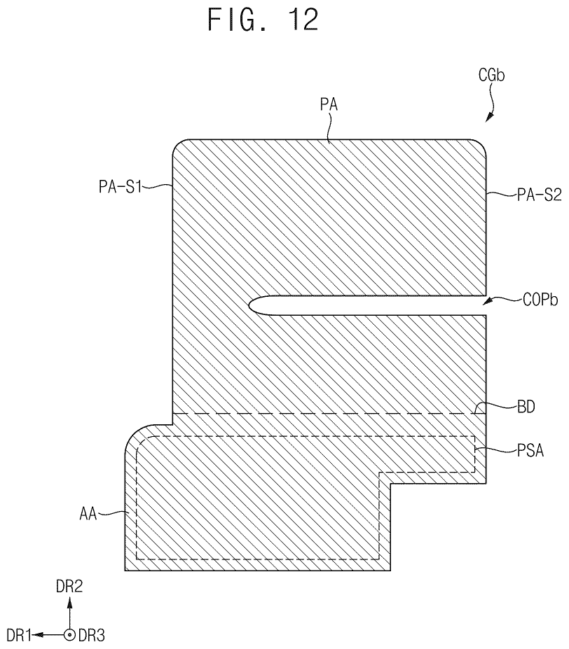

Hereinafter, various embodiments of a protecting film and a cutout portion are to be described with reference to FIGS. 12, 13, 14, 15, and 16. Substantially same reference numerals are assigned to substantially same components, and detailed descriptions thereof may be omitted.

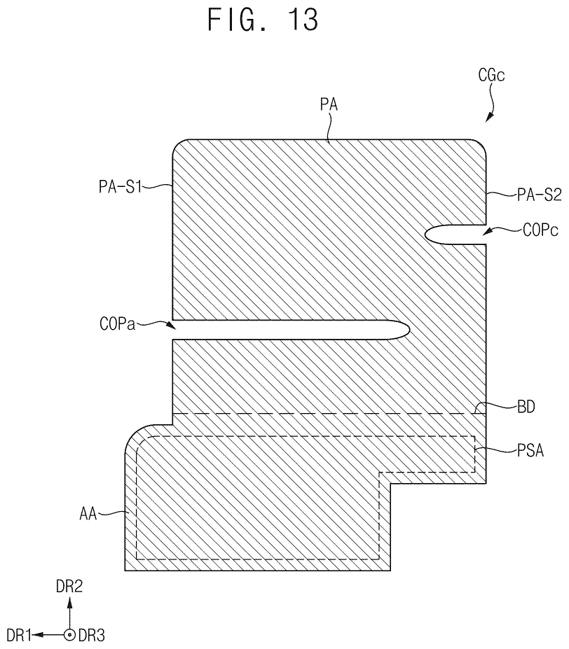

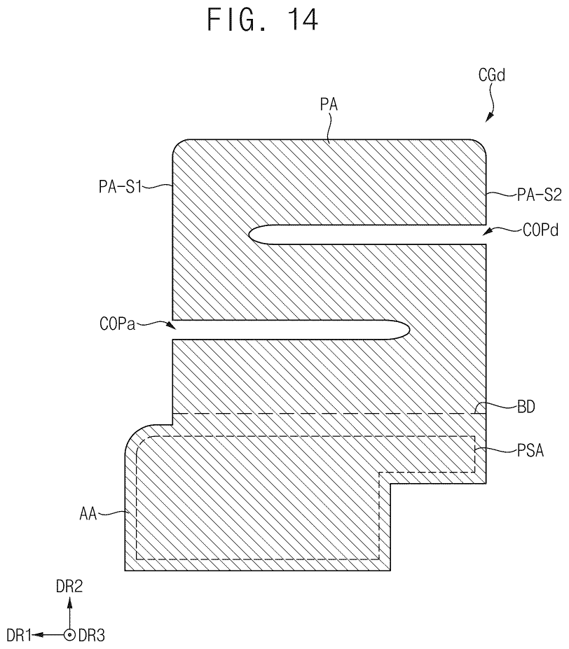

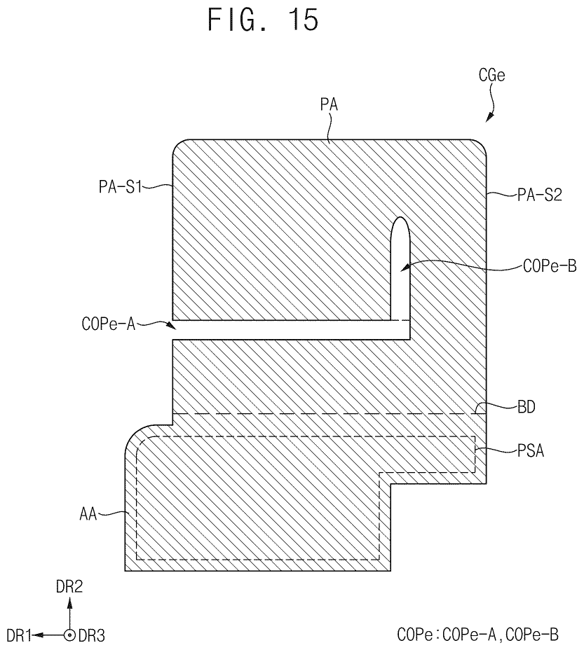

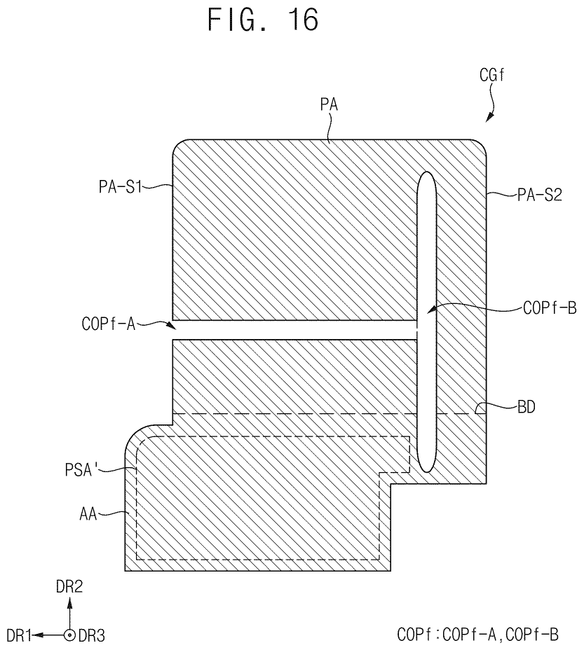

FIG. 12 is a bottom view illustrating a protecting film, according to an embodiment. FIG. 13 is a bottom view illustrating a protecting film, according to an embodiment. FIG. 14 is a bottom view illustrating a protecting film, according to an embodiment. FIG. 15 is a bottom view illustrating a protecting film, according to an embodiment. FIG. 16 is a bottom view illustrating a protecting film, according to an embodiment.

In an embodiment and referring to FIG. 12, a protecting film CGb may define a second cutout portion COPb. For example, a protrusion portion PA may define a second cutout portion COPb. Unlike the first cutout portion COPa of FIG. 8, the second cutout portion COPb may be a portion in which at least a portion of the protrusion portion PA is removed from the second surface PA-S2 of the protrusion portion PA. The second cutout portion COPb may be spaced apart from the first surface PA-S1 of the protrusion portion PA in plan view. In an embodiment, the second cutout portion COPb may be directed to be substantially parallel to the boundary surface BD where the protrusion portion PA and the attachment portion AA contact each other. That is, the second cutout portion COPb may extend in the first direction DR1.

In an embodiment and referring to FIG. 13, a protecting film CGc may define a first cutout portion COPa and a third cutout portion COPc. For example, a protrusion portion PA may define a first cutout portion COPa and a third cutout portion COPc. The first cutout portion COPa may be substantially same as the first cutout portion COPa of FIG. 8. The third cutout portion COPc may be a portion obtained by removing at least a portion of the protrusion portion PA from the second surface PA-S2 of the protrusion portion PA. The third cutout portion COPc may be spaced apart from the first surface PA-S1 of the protrusion portion PA in a plan view. In an embodiment, the third cutout portion COPc may be directed to be substantially parallel to the boundary surface BD at which the protrusion portion PA and the attachment portion AA contact with each other. That is, the third cutout portion COPc may extend in the first direction DR1. That is, the third cutout portion COPc may be directed to be substantially parallel to the first cutout portion COPa. In an embodiment, the third cutout portion COPc may not overlap the first cutout portion COPa in the second direction DR2.

In an embodiment and referring to FIG. 14, a protecting film CGd may define a first cutout portion COPa and a fourth cutout portion COPd. For example, the protrusion portion PA may define a first cutout portion COPa and a fourth cutout portion COPd. The first cutout portion COPa may be substantially same as the first cutout portion COPa of FIG. 8. The fourth cutout portion COPd may be a portion obtained by removing at least a portion of the protrusion portion PA from the second surface PA-S2 of the protrusion portion PA. The fourth cutout portion COPd may be spaced apart from the first surface PA-S1 of the protrusion portion PA in plan view. In an embodiment, the fourth cutout portion COPd may be directed to be substantially parallel to the boundary surface BD at which the protrusion portion PA and the attachment portion AA contact each other. That is, the fourth cutout portion COPd may extend in the first direction DR1. That is, the fourth cutout portion COPd may be directed to be substantially parallel to the first cutout portion COPa. In an embodiment, the fourth cutout portion COPd may at least partially overlap the first cutout portion COPa in the second direction DR2.

In an embodiment and referring to FIG. 15, a protecting film CGe may define a fifth cutout portion COPe. For example, the protrusion portion PA may define the fifth cutout portion COPe. The fifth cutout portion COPe may be a portion obtained by removing at least a portion of the protrusion portion PA from the first surface PA-S1 of the protrusion portion PA. The fifth cutout portion COPe may be spaced apart from the second surface PA-S2 of the protrusion portion PA in a plan view. In an embodiment, the fifth cutout portion COPe may include a first portion COPe-A and a second portion COPe-B. The first portion COPe-A may be a portion that is directed to be substantially parallel to the boundary surface BD. That is, the first portion COPe-A may extend in the first direction DR1. The second portion COPe-B may be a portion extending in the second direction DR2 from one end of the first portion COPe-A. For example, the second portion COPe-B may be directed to be substantially parallel to the first surface PA-S1 and the second surface PA-S2 of the protrusion portion PA, but the invention is not limited thereto. The first portion COPe-A and the second portion COPe-B may be connected to each other.

In an embodiment and referring to FIG. 16, a protecting film CGf may include an attachment portion AA and a protrusion portion PA. The attachment portion AA may include a film adhesive layer PSA′. The protecting film CGf may define a sixth cutout portion COPf. The sixth cutout portion COPf may include a first portion COPf-A and a second portion COPf-B. The first portion COPf-A may be a portion defined in the protrusion portion PA. For example, the first portion COPf-A may be a portion directed to be substantially parallel to the boundary surface BD in a portion of the protrusion area (e.g., the protrusion area PAA of FIG. 10). That is, the first portion COPf-A may be a portion extending in the first direction DR1 in a portion of the protrusion area. The second portion COPf-B may be connected to one end of the first portion COPf-A. The second portion COPf-B may be a portion defined in the protrusion portion PA and the attachment portion AA. For example, the second portion COPf-B may be a portion extending in the second direction DR2 from a portion of the protrusion area and a portion of the attachment area (e.g., the attachment area NAA of FIG. 10). The second portion COPf-B may cross the boundary surface BD. In this case, the second portion COPf-B may be spaced apart from the film adhesive layer PSA in a plan view. That is, width of the film adhesive layer PSA′ in the first direction DR1 may be set so that the film adhesive layer PSA does not overlap the second portion COPf-B in a plan view. The first portion COPf-A and the second portion COPf-B may be connected to each other.

In an embodiment, the display module (e.g., the display module DM of FIG. 4) may be applied to various electronic devices. For example, after the display module is applied to the electronic device, the protecting film (e.g., the protecting film CGa of FIG. 8, the protecting film CGb of FIG. 12, the protecting film CGc of FIG. 13, the protecting film CGd of FIG. 14, the protecting film CGe of FIG. 15, and the protecting film CGf of FIG. 16) and the release film (e.g., the release film LN of FIG. 3) may be removed from the display panel (e.g., the display panel 10 of FIG. 3).

FIG. 17 is a block diagram illustrating an electronic device, according to embodiments.

In an embodiment and referring to FIG. 17, an electronic device 100 may include a display unit 110, a processor 120, a memory 130, and a power module 140.

In an embodiment, the processor 120 may include at least one of a central processing unit (“CPU”), an application processor (“AP”), a graphic processing unit (“GPU”), a communication processor (“CP”), an image signal processor (“ISP”), and a controller.

In an embodiment, data information necessary for operation of the processor 120 or the display unit 110 may be stored in the memory 150. When the processor 120 executes an application stored in the memory 150, an image data signal and/or an input control signal is transmitted to the display unit 110, and the display unit 110 may process received signal and output image information through a display screen.

In an embodiment, the power module 140 may include a power supply module such as a power adapter or a battery device, and a power conversion module that converts power supplied by the power supply module to generate power required for operation of the electronic device 100.

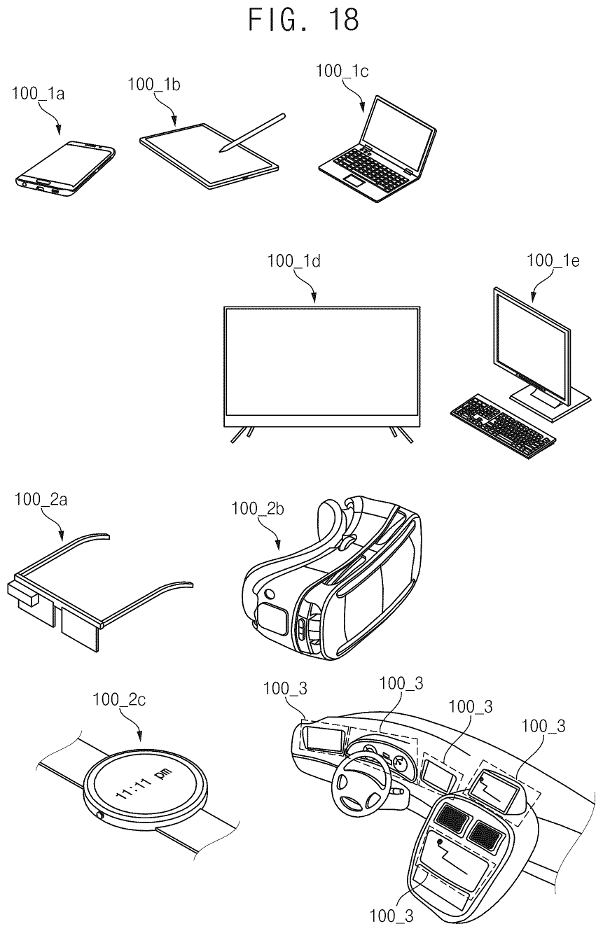

FIG. 18 are graphical images of electronic devices, according to various embodiments.

In an embodiment and referring to FIG. 18, various electronic devices to which display modules are applied may include not only electronic devices for image display such as a smartphone 100_1a, a tablet PC 100_1b, a laptop 100_1c, a TV 100_1d, a desk monitor 100_1e, and/or the like, but also wearable electronic devices including display modules such as a smart glass 100_2a, a head mounted display 100_2b, a smart watch 100_2c, and/or the like, vehicle electronic device 100_3 including display modules such as a vehicle's instrument panel, a center fascia, a center information display (“CID”) disposed on a dashboard, a room mirror display, and/or the like.

The invention can be applied to various display devices. For example, the invention is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the invention without materially departing from the novel teachings and advantages of the invention. Accordingly, all such modifications are intended to be included within the scope of the invention. Therefore, it is to be understood that the foregoing is illustrative of various embodiments and is not to be construed as limited to the specific embodiments disclosed, and that modifications to the invention are intended to be included within the scope of the invention.

What is claimed is:

1. A protecting film comprising:
an attachment portion configured to be attached to an object; and
a protrusion portion protruding from one side of the attachment portion and including a first surface and a second surface disposed opposite to the first surface, wherein the protrusion portion defines a first cutout portion from which at least a portion is removed from the first surface.

2. The protecting film of claim 1, wherein the first cutout portion is directed parallel to a boundary surface at which the attachment portion and the protrusion portion contact each other.

3. The protecting film of claim 1, wherein the first cutout portion is spaced apart from the second surface in a plan view.

4. The protecting film of claim 1, wherein the attachment portion includes,
a base layer; and
a film adhesive layer bonding the base layer and the object together.

5. The protecting film of claim 4, wherein an adhesive force of the film adhesive layer is equal to or less than about 50 gf/inch.

6. The protecting film of claim 1, wherein the protrusion portion defines a second cutout portion from which at least a portion is removed from the second surface.

7. The protecting film of claim 6, wherein the first cutout portion and the second cutout portion are directed parallel to each other.

8. The protecting film of claim 7, wherein the protrusion portion protrudes from the one side of the attachment portion in a first direction, and
the first cutout portion and the second cutout portion at least partially overlap each other in the first direction.

9. The protecting film of claim 7, wherein the second cutout portion is spaced apart from the first surface in a plan view.

10. The protecting film of claim 1, wherein a boundary surface at which the attachment portion and the protrusion portion contact each other extends in a first direction, and wherein,
the first cutout portion includes,
a first portion extending in the first direction; and
a second portion extending from one end of the first portion in a second direction crossing the first direction.

11. The protecting film of claim 1, wherein the first cutout portion is spaced apart from the attachment portion in a plan view.

12. A protecting film comprising:
a base layer including an attachment area attached to an object, and a protrusion area protruding from the attachment area, the base layer defining a cutout portion, wherein the cutout portion includes a first portion extending in a first direction from a portion of the protrusion area and a second portion extending in a second direction crossing the first direction in a portion of the protrusion area and a portion of the attachment area; and
a film adhesive layer disposed in the attachment area under the base layer.

13. The protecting film of claim 12, wherein the first portion of the cutout portion is directed parallel to a boundary surface at which the attachment area and the protrusion area contact each other.

14. The protecting film of claim 13, wherein the second portion of the cutout portion crosses the boundary surface at which the attachment area and the protrusion area contact each other.

15. The protecting film of claim 12, wherein the second portion of the cutout portion is spaced apart from the film adhesive layer in a plan view.

16. The protecting film of claim 12, wherein the first portion and the second portion of the cutout portion are connected to each other.

17. An electronic device comprising:
a display panel;
a protecting film disposed under the display panel, the protecting film including:
an attachment portion configured to be attached to the display panel; and
a protrusion portion protruding from one side of the attachment portion, including a first surface and a second surface disposed opposite to the first surface, wherein the protrusion portion defines a first cutout portion from which at least a portion is removed from the first surface; and
a memory where data information is stored.

18. The electronic device of claim 17, wherein the first cutout portion is directed parallel to a boundary surface at which the attachment portion and the protrusion portion contact each other.

19. The electronic device of claim 17, wherein the display panel defines a hole, and the protecting film at least partially overlaps the hole in a plan view.

20. The electronic device of claim 17, wherein the protrusion portion defines a second cutout portion from which at least a portion is removed from the second surface.
